(19) United States
(12) Patent Application Publication
(10) Pub. No.: US 2021/0147974 A1
(43) Pub. Date: May 20, 2021

(54) MAGNETIC-FIELD-ASSISTED PLASMA COATING SYSTEM

(71) Applicants: Board of Trustees of Michigan State University, East Lansing, MI (US); Fraunhofer USA, East Lansing, MI (US)

(72) Inventors: Thomas SCHUELKE, Pinckney, MI (US); Michael BECKER, East Lansing, MI (US); Lars HAUBOLD, East Lansing, MI (US); Qi Hua FAN, Okemos, MI (US)

(73) Assignees: Board of Trustees of Michigan State University, East Lansing, MI (US); Fraunhofer USA, East Lansing, MI (US)

(21) Appl. No.: 16/620,341

(22) PCT Filed: Jun. 7, 2018
(86) PCT No.: PCT/US2018/036474

§ 371 Date: Dec. 6, 2019

Related U.S. Application Data
(60) Provisional application No. 62/516,797, filed on Jun. 8, 2017.

(51) Int. Cl. C23C 14/32; C23C 14/06; F02F 1/00

(52) U.S. Cl. CPC C23C 14/325; F02F 2200/00; F02F 1/00; C23C 14/0605

(57) ABSTRACT

A magnetic-field-assisted plasma coating system and method are provided. In another aspect, a coating system employs a cathode with a linearly moveable magnetic field. A further aspect employs a workpiece as an anode within which is located an elongated cathode which internally coats a bore of the workpiece. Still another aspect of the present system and method employs an elongated and hollow cathode with at least one magnetic source therein. In yet another aspect, end caps or plates seal against one or more open ends of a workpiece bore to be coated, with a cathode inserted into the bore and a vacuum being created within the bore such that the workpiece itself defines at least a portion of a vacuum chamber.

### CROSS-REFERENCE TO RELATED APPLICATIONS

This application claims the benefit of U.S. Provisional Patent Application No. 62/516,797, filed Jun. 8, 2017, which is incorporated by reference herein.

### BACKGROUND

The present disclosure generally pertains to coating systems and more particularly to a magnetic-field-assisted plasma coating system.

Increasing fuel efficiency is a great challenge in the automotive industry. Effective approaches to meeting the fuel efficiency requirements are to reduce the weight of vehicles and to increase the engine performance. In passenger vehicles, approximately 15% of fuel energy is spent to overcome engine friction. Therefore, optimizing the performance of engines is desirable to improving fuel efficiencies.

The vehicle manufacturers have recently been converting the heavy mass of engine blocks from cast iron to aluminum which delivers a 40% to 50% reduction of engine weight. However, aluminum is a “soft” metal and does not withstand the constant friction of pistons and piston rings scraping up and down the bore surface. Two ways have been adopted by the automotive manufacturers to protect aluminum engine cylinder bores: install iron liners or place a wear-resistant layer on the bore surface. But each conventional approach has its limitations.

Most U.S. automotive manufacturers use iron liners where each wall is approximately 3 mm thick. The room that liners require cannot always be taken from the space between each cylinder because there must be sufficient material between the cylinder bores to maintain the structural strength of the engine block. As a result, the overall engine size and weight increase which is often unacceptable. Most importantly, the friction and wear between the liner surface and the piston rings are significant and subsequently limit the fuel efficiency as well as horsepower and torque. On the other hand, many Japanese and European engines cannot afford the weight penalty imposed by the liners due to the high cost of fuel in those regions. In this case, the cylinder bore surfaces are made more wear-resistant by using hard coatings or chemical surface treatments. Unfortunately, the existing coatings and surface treatments are either expensive or cannot provide satisfactory wear resistance with low friction coefficients.

Therefore, a strong need continues to exist for further increasing wear-resistance of cylinder bores and liners while further reducing the friction between these parts and the piston rings to promote fuel efficiency and performance. Two technologies have recently been investigated, but with limited success. (1) Plasma spray coatings offer a wear-resistant surface, which protects the engine bore from piston ring wear. This technology requires extensive pre- and post-bore processing to create the desired surface condition for coating adherence and smoothness. Another problem of the spray coating is the significant thermal load transferred to the engine block during coating, which leads to large thermally induced mechanical stresses that compromise the coating reliability. (2) Plasma enhanced chemical vapor deposition has been developed to coat working surfaces with hard diamond-like carbon films. Poor coating adhesion may occur with this prior process, however, due to the low energies of ions created in the plasma. Furthermore, this type of diamond-like carbon coating is synthesized by breaking down hydrocarbon precursor gases, which intrinsically contain hydrogen. Hydrogenated films tend to react with sulfur compounds in oil lubricants and form undesirable sludge layers. Furthermore, such hydrogenated carbon coatings tend to be on the softer side of the available range of diamond-like carbon materials. Also, the reactive chemical gases need proper scrubbing for safety reasons. Hence, integrating such prior chemical vapor deposition processes into an automotive manufacturing line would require large investments.

A beneficial cathodic arc deposition process capable of producing super-hard tetrahedrally bonded amorphous carbon thin films (“ta-C”) is disclosed in L. Haubold, T. Schuelke, M. Becker, G. Woodrough, “The Influence of the Surface Texture of Hydrogen-Free Tetrahedral Amorphous Carbon Films on their Wear Performance,” Diamond and Related Materials 19 (2-3), 225 (March 2010); and U.S. Pat. No. 8,911,868 entitled “Coating Based on Diamond-Like Carbon” which issued to Scheibe et al. on Dec. 16, 2014, and is incorporated by reference herein. As a physical vapor deposition technology, this conventional cathodic arc process relies on line-of-sight access from the external source material to the workpiece surface, which has made it difficult to use with coating inner diameter surfaces such as cylinder bores.

Finally, U.S. Pat. No. 8,387,561 entitled “Method and Apparatus for Cathodic Arc Ion Plasma Deposition” which issued to Weaver et al. on Mar. 5, 2013, is incorporated by reference herein. This patent discloses a permanent magnet inside a cathode, however, a separate anode and a separate vacuum chamber are required which disadvantageously add expense and complexity.

### SUMMARY

In accordance with the present invention, a magnetic-field-assisted plasma coating system and method are provided. In another aspect, a coating system employs a cathode with a linearly moveable magnetic field. A further aspect employs a workpiece as an anode within which is located an elongated cathode which internally coats a bore of the workpiece. Still another aspect of the present system and method employs an elongated and hollow cathode with at least one magnetic source therein. In yet another aspect, end caps or plates seal against one or more open ends of a workpiece bore to be coated, with a cathode inserted into the bore and a vacuum being created within the bore such that the workpiece itself defines at least a portion of a vacuum chamber.

The present magnetic-field-assisted plasma coating system advantageously uses a magnetically enhanced cathodic arc plasma to efficiently deposit low-friction coatings, such as a super-hard tetrahedral amorphous carbon (“ta-C”) coating, onto an inner bore surface of an internal combustion engine and/or a tube. Furthermore, a magnetic field advantageously moves along a cathode to guide and control plasma arcs during a coating process. The present system and method are expected to greatly reduce the friction coefficient and increase wear resistance, thereby extending engine cylinder durability and improving fuel efficiency. Moreover, the present system and method advantageously deposit ta-C coatings or films with a thickness of about 0.01-30 microns, which does not require an enlargement of the engine packaging size or weight. It is also advantageous that the cathode is stationary relative to the workpiece through the entire coating process, thereby leading to thickness consistency of the coating along the workpiece bore. Additional advantages and features of the present invention will become apparent from the following description and appended claims, taken in conjunction with the accompanying drawings.

### BRIEF DESCRIPTION OF THE DRAWINGS

FIG. 1 is a perspective view showing an automotive vehicle engine workpiece employed with the present system and method;

FIG. 2 is a cross-sectional view, taken along line 2-2 of FIG. 1, showing a portion of the engine employed with the present system and method;

FIG. 3 is a longitudinal sectional view showing a first embodiment of the present system and method;

FIG. 4 is a cross-sectional view, taken along line 4-4 of FIG. 3, showing the first embodiment system and method;

FIG. 5 is a longitudinal sectional view showing a second embodiment of the present system and method;

FIG. 6 is a longitudinal sectional view showing a third embodiment of the present system and method;

FIG. 7 is a longitudinal sectional view showing a fourth embodiment of the present system and method; and

FIG. 8 is a longitudinal sectional view showing a fifth embodiment of the present system and method.

### DETAILED DESCRIPTION

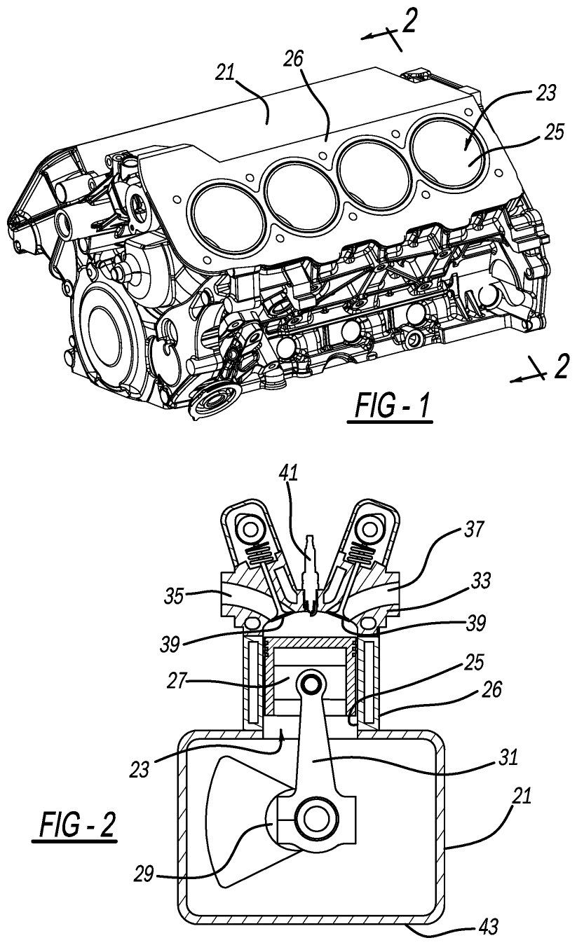

Referring to FIGS. 1 and 2, an automotive vehicle has an internal combustion engine 21 within which are multiple bores 23 defined by cylinder surfaces 25 of an engine block workpiece 26 within which pistons 27 linearly move. Furthermore, a crank shaft 29 is rotatably connected to each piston 27 by way of a connecting rod 31. A cylinder head 33, with intake and exhaust passages 35 and 37, as well as valves 39 and a spark plug 41, are located at one end of the cylinder block 26 while a crank case 43 is located at the opposite end of the cylinder block 26.

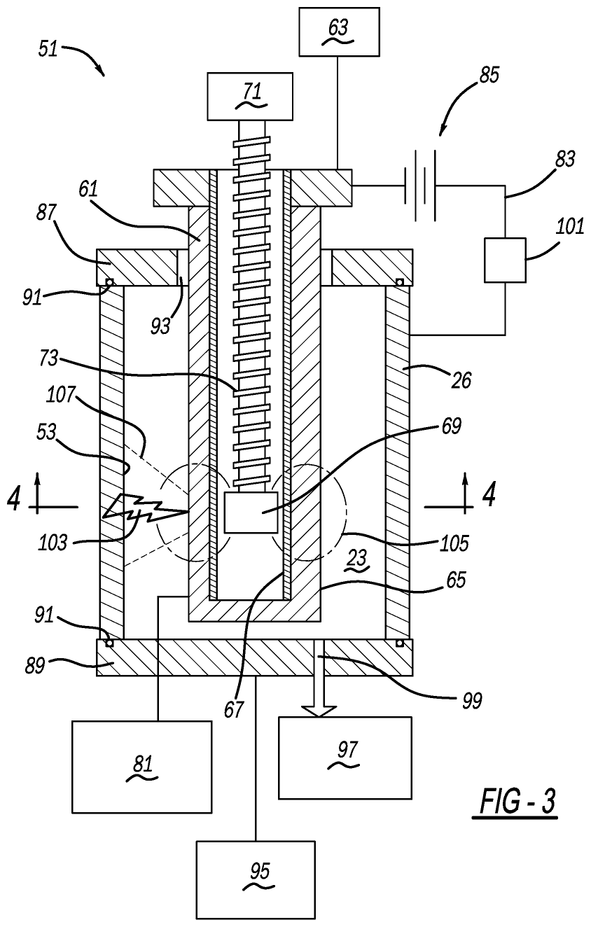

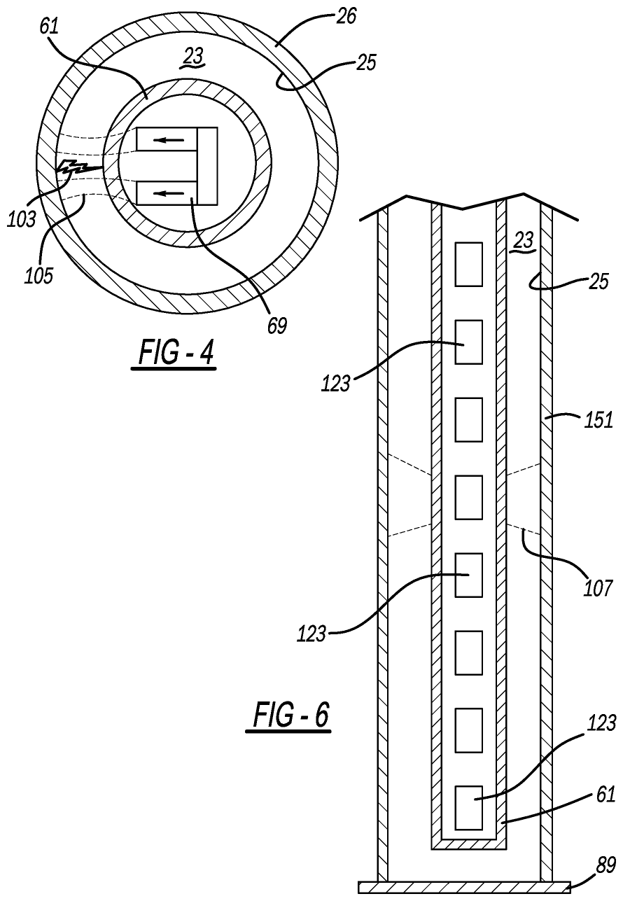

FIGS. 3 and 4 illustrate a first embodiment of a magnetic-field-assisted plasma coating system 51. In this construction, engine block 26 is the workpiece to be coated with ta-C 53, and serves as an anode in the overall system and machine. A longitudinally elongated cathode 61 is concentrically and coaxially moveable within each bore 23 by a robotic arm 63 or other automated mechanism, from a retracted position to an advanced position (as shown in FIG. 3). Cathode 61 has a generally cylindrical outside surface 65 made from graphite. Furthermore, cathode 61 has a longitudinally elongated and hollow interior 67 within which is located a magnetic source, preferably a permanent magnet 69. The magnetic force at exterior surface 65 of cathode 61 is preferably 1-20 milliteslas.

An actuator 71 and driven transmission 73 linearly move magnet 69 in the advancing and retracting directions within cathode 61. A programmable controller 101 of an electrical circuit 83 energizes and de-energizes actuator 71. Actuator 71 may be an automatically energized electric motor or fluid-powered cylinder. Transmission 73 may be a jack screw (as shown) with an interior of magnet 69 being attached to and moveable with an internally threaded nut or ball, a cable and slide mechanism, a piston rod if a fluid driven cylinder is used, or the like.

A longitudinal length of cathode 61 is at least twice and more preferably at least five times a lateral diameter dimension of cathode 61. Moreover, an arc ignitor 81 is located adjacent cathode 61 within cylinder bore 23 for initiating a plasma arc between cathode 61 and workpiece anode 26. Electrical circuit 83 connects a direct current power source 85 with both cathode 61 and workpiece anode 26. Alternately, power source 85 may combine direct and pulsed current, especially if carbon cathodes are employed.

A pair of opposed plates or end caps 87 and 89 of the present system and machine are moveable from a retracted position to an advanced position (as shown in FIG. 3) where elastomeric or rubber o-rings, skirts or bulb seals 91 contact against ends of engine block workpiece 26 in order to provide an entirely enclosed area within each bore 23. An aperture 93 is centrally located within end cap 87 allowing entry of cathode 61 associated with each bore 23. An elastomeric or rubber bulb seal, o-ring or skirt may be employed therebetween in order to seal aperture 93 after full insertion of cathode 61. An automated mechanism 95 such as a robotic arm, actuator-driven linkage, actuator-driven ball screw or the like, controlled by controller 101, operably moves end caps 87 and 89 from their retracted positions to their sealing and advanced positions against engine block 26. Alternately, a robotic or other mechanism may move the engine block relative to one of the stationary end plates with the opposite end cap thereafter being advanced to enclose the bore. Alternately, the cathode can be removeably attached to and moveable with the end cap to make sealing easier and only requiring a single actuator to simultaneously advance both components.

A vacuum source, such as a pump 97, is thereafter actuated to create a reduced pressure or vacuum through an outlet 99 in one of the caps 89. The vacuum pressure within bore 23 is preferably at least 10⁻³ and more preferably also less than 10⁻⁶ Torr for a bore diameter of about 10 cm and a cathode outer diameter of about 2 cm. It is noteworthy that in one exemplary configuration, exterior surface 65 of cathode 61 is only 2-5 cm away from inner bore surface 25 of engine block workpiece 26, thereby allowing the vacuum pressure that is sufficiently low for successful vapor deposition to be created relatively quickly and also subsequently allowing for relatively fast plasma coating especially as compared to conventional attempts.

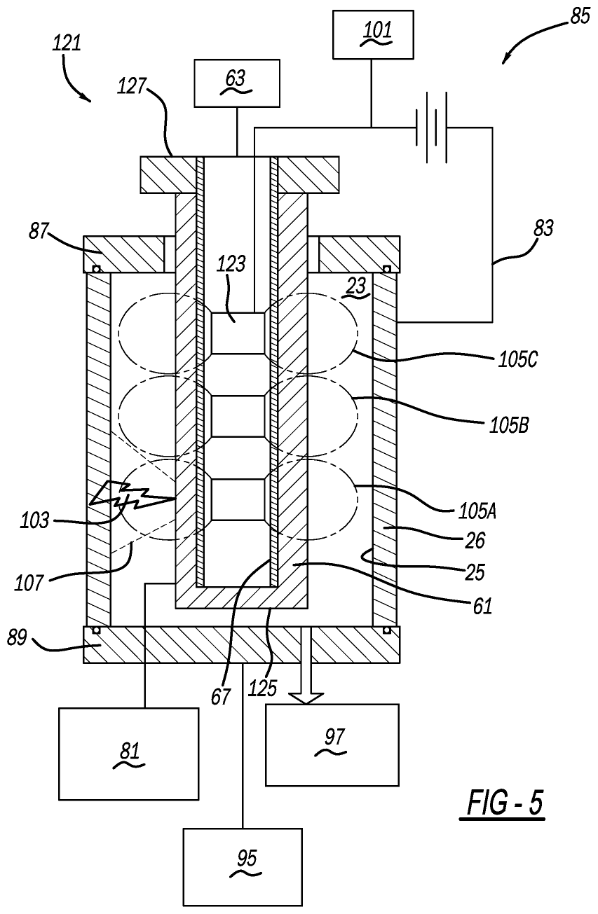

During operation, after the seal is created and vacuum drawn, programmable controller 101 causes ignitor 81 to generate an electrical arc 103 from anode workpiece 26 to cathode 61 within the vacuum. This causes ionization of the cathodic material at various evaporative spots on the cathode adjacent a magnetic field 105 created by magnet 69. The magnetic field will control and guide the location of these cathode spots which in turn controls and guides where the plasma ionization is generated and emitted from. Thus, the ionic ta-C coating 107 is transferred within at least a portion of the magnetic field, and in a generally expanding fan-like side view shape, from the cathode to the anode workpiece 26. Based on predetermining time and speed values, programmable controller 101 subsequently causes actuator 71 to move magnet 69 in the linearly retracting and/or advancing direction(s) within the cathode in order to linearly move the magnetic field therealong. A tunnel magnetic field shape (as shown in FIG. 5) allows the cathode spots to run around the diameter within a limited vertical range of the cylindrical cathode. The limits are set by the magnetic field. When the field moves up and down, the arc spots follow the field but continue to run around the circumference of the cathode. The ionic cathode spots will follow the magnetic field 105 during this magnet movement thereby uniformly and quickly coating inner surface 25 of workpiece anode 26 without requiring movement of the cathode itself or movement of the workpiece during the coating operation. A single or multiple coating passes may be employed.

When completed, programmable controller 101 will electrically terminate the electrical arc, de-energize the vacuum pump 97 and cause a relief valve to vent the vacuum chamber to ambient outside air pressure, energize mechanism 63 to withdraw and retract cathode 61, and energize mechanism 95 to retract end caps 87 and 89. Thereafter, the engine block is moved from the workstation and a new engine block is subsequently inserted therein for another coating cycle. It is envisioned that the entire coating process, from sealing of the bore through unsealing of the bore will be five minutes or less, and more preferably two minutes or less.

The present system and method are expected to achieve an sp³ bond fraction percentage for carbon atoms of about 20-85%, which is controlled by the energy of the carbon ions and substrate temperature during plasma coating. It is envisioned that the present system and method will employ an ion impact energy of about 10-250 eV, which is far superior to traditional sputter coating of less than 5 eV. Furthermore, room temperature use of the present system and method are preferred to increase the fraction percentage, although temperatures less than 400° C. may also suffice.

The cathode is expected to generate less than 120° C. at its outer surface during the coating process, if about 2 kW of electrical power for about 120 seconds is employed. In this advantageously expected cool-cathode situation, cooling of the permanent magnet may be performed through a copper cylinder externally located adjacent to the proximal end of the cathode which acts as a heat sink, thereby avoiding the use of cooling fluid. Alternately, a hollow copper fluid-carrying tube with internal cooling channels, surrounded by a carbon sleeve or the like, is optionally located within the cathode around the permanent magnet. This alternate tube and sleeve serve to cool the magnet.

In an optional feature, the present system and method may employ a prior or subsequent separate cathode made of a different conductive material, such as a metal (for example: chromium, tantalum, niobium, titanium), using the same process within the bore vacuum before the use of the graphite cathode to deposit metals or metal nitrides. Metal nitrides would be deposited reactively, that is, by adding a partial pressure of nitrogen to the process during arc evaporation of the metal. This multiple cathode process allows for initial coating of the inner bore surface 25, especially if aluminum, with the more ductile metal material prior to application of the much harder ta-C coating layer to minimize cracking of the aluminum workpiece.

Reference should now be made to FIG. 5. A second exemplary embodiment of a magnetic-field-assisted coating system 121 is essentially the same as that of the FIG. 3 embodiment, however, the magnetic source and operation are different. In this version, the magnetic source includes at least two, and more preferably three, electromagnets 123 stationarily located within the hollow interior 67 of elongated cathode 61. The electromagnets are spaced apart from each other with an air gap or insulation therebetween and are each electrically connected to electrical circuit 83 and the associated programmable controller 101. Each electromagnet includes a conductive wire wrapped around an iron core. In operation after bore 23 is sealed and vacuum pump 97 draws the vacuum in each bore, controller 101 will cause electrical current to be sequentially provided to each of the electromagnets 123 based on predetermined time and speed values. This causes a linear or longitudinal sequential energization of electromagnets 123 which energizes a first electromagnetic field 105A adjacent a distal end 125 of cathode 61 for transmission of arc 103 and plasma ta-C ions 107 thereat. Next, this first electromagnet is de-energized and a second electromagnet is energized to create a middle magnetic field 105B. Accordingly, the electric arc 103 and coating ions 107 linearly follow to this middle magnetic field location. Then, the middle electromagnet is de-energized by controller 101 and the third electromagnet, closest to the proximal cathode end 127, is energized to create a magnetic field 105C thereat. This again linearly moves arc 103 and coating ions 107 to this third magnetic field location. This construction beneficially does not require any moving parts during the coating process after sealing of the end caps.

FIG. 6 illustrates a third exemplary embodiment with a longitudinally elongated cathode 61 having multiple spaced apart electromagnets 123 as in the FIG. 5 embodiment. However, this FIG. 6 system and method are employed with an anode workpiece 151 defined as an elongated metallic tube or pipe. This is ideally suited for internally coating the interior surface 25 surrounding bore 23 with a diamond-like hard coating of ta-C. This arrangement is ideally suited in a tube 151 of at least 3 meters in longitudinal length which can be employed for transporting or carrying abrasive liquids or slurries, such as sand, or corrosive materials such as those found in sulphuric acid or carbon dioxide contaminated oil from tar-sand extraction. As an option if the tubular workpiece is long, two mirrored image cathodes may be inserted, one in each end, through their corresponding end caps.

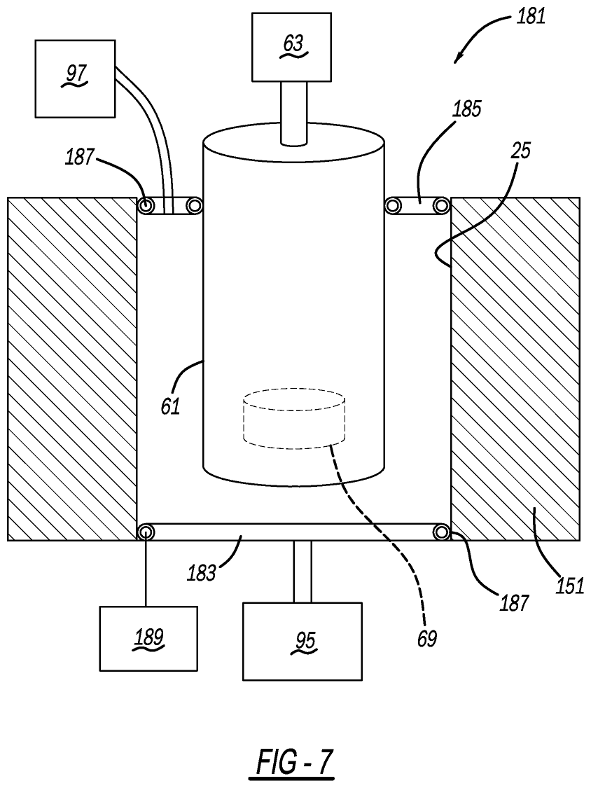

A fourth exemplary embodiment system 181 is shown in FIG. 7. This embodiment is similar to any of those previously discussed herein above, however, end caps 183 and 185 employ inflatable bulb seals 187, each having a generally circular or oval enclosed cross-sectional shape surrounding the periphery thereof. Seals 187 are deflated when end caps 183 and 185 are inserted into ends of bore 23 and then a positive air pressure pump 189 supplies air to inflate the seals to create a pressure resistant seal between the end caps and inner bore surface 25 and/or between end cap 185 and an exterior of cathode 61.

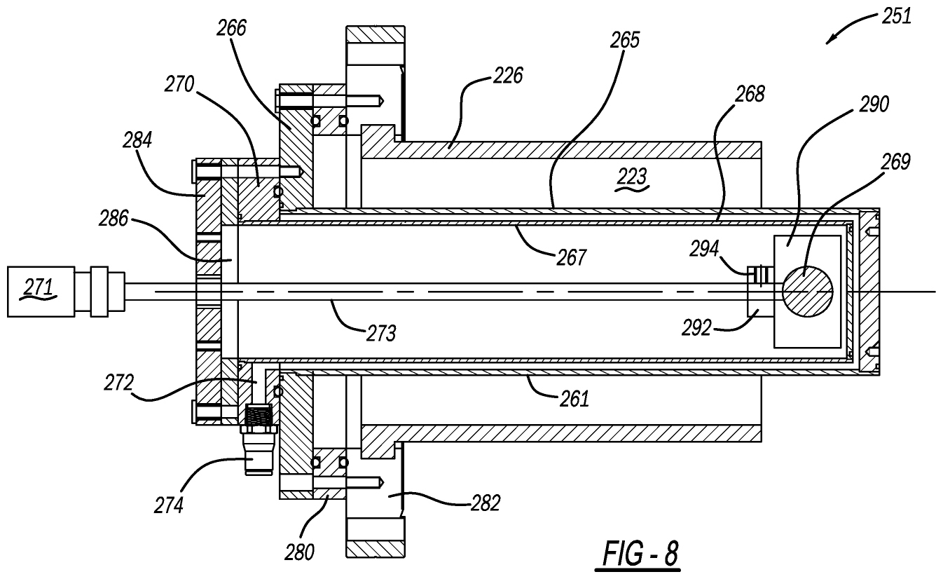

FIG. 8 depicts a fifth exemplary embodiment of a magnetic-field-assisted plasma coating system 251 which is the same as the first embodiment except as follows. System 251 employs a machine including an outer cathode 261 with a cylindrical section 265 and a flange section 266. A cylindrical ring target material can be attached to outer cathode 261. The machine of system 251 further provides an inner cathode 268 including a cylindrical section 267 and a flange section 270. Flange section 270 overlies and is secured to flange section 266, while cylindrical section 267 is concentrically located internal to cylindrical section 265 with a lateral gap therebetween. A cooling conduit 272 and ports 274 are associated with inner cathode 268 for supplying cooling fluid between cylindrical sections 267 and 265.

An insulator 280 is mounted between flange 266 and a vacuum flange 282 to which they are fastened. Moreover a motor support plate 284 is fastened to flange 270 with an insulator 286 therebetween. An actuator 271, such as an electric motor, and a longitudinally elongated and solid transmission shaft 273 are moveably coupled to support plate 284. Shaft 273 is operably driven by actuator 271.

A magnet holder 290 is retained to a distal end of shaft 273 via a connector 292 having a set screw 294 or other fastener. A permanent magnet 269 of a cylindrical shape (as illustrated in cross-section), ring (not shown), or rectangular-cubic shape (not shown) is secured within holder 290 for longitudinal and/or rotational movement by shaft 273 and motor 271. Magnet holder 290 is electrically isolated from cathode 268. Cathodes 268 and 261, and magnet 269 within the cathodes, are longitudinally insertable into and removeable from an open access end of an internal bore 223 of an engine or pipe workpiece 226. Any of the previously discussed end caps and/or seals may be employed to create a vacuum chamber within the internal bore area using workpiece 226 to define part of the vacuum chamber while the workpiece also acts as an anode. An exterior of the workpiece may be exposed to ambient air since a separate vacuum chamber is not necessary.

While various embodiments of the present system and method have been discussed, additional variations may be employed. For example, automated actuators, mechanisms and controllers have been disclosed for moving and activating the preferred machine, but manual movement and control may alternately be employed although various advantages may not be achieved. Furthermore, each of the features may be interchanged and intermixed between any and all of the embodiments. Changes and modifications are not to be regarded as a departure from the spirit or the scope of the present invention.

1. A coating system comprising:
an elongated cathode;
at least one magnetic source located within the cathode;
a workpiece surrounding an outer surface of the cathode, the workpiece acting as an anode;
a vacuum source adapted to create a vacuum around the cathode;
the at least one magnetic source being adapted to cause a magnetic field to linearly move along the cathode; and
an interior wall of the workpiece, surrounding the outer surface of the cathode, defining part of a vacuum chamber connected to the vacuum source.

2. The system of claim 1, wherein:
the outer surface of the cathode includes graphite; and
an ionic ta-C coating is operably emitted onto the workpiece.

3. The system of claim 1, further comprising at least one end cap removeably located over at least one opening of the workpiece defining part of the vacuum chamber, the vacuum chamber being entirely within a hollow area inside the workpiece.

4. The system of claim 1, further comprising at least one seal removeably located over at least one opening of the workpiece to define part of the vacuum chamber, the vacuum chamber being entirely within a hollow area inside the workpiece.

5. The system of claim 1, further comprising at least two of the magnetic sources located within a hollow interior of the cathode, the magnetic sources being longitudinally arranged relative to each other, and a magnetic force at the outer surface of the cathode being 1-20 milliteslas.

6. The system of claim 5, wherein the at least two magnetic sources are electromagnets which are longitudinally spaced apart from each other and located within a hollow interior of the cathode, further comprising a programmable controller and an electrical circuit being connected to the electromagnets.

7. The system of claim 1, further comprising an exterior of the workpiece being exposed to ambient air during plasma coating inside of the workpiece.

8. The system of claim 1, further comprising a solid and longitudinally elongated transmission shaft coaxially extending within a hollow center of the cathode, the shaft being attached to the magnetic source and operably moving the magnetic source in longitudinal and rotational directions during plasma coating of an interior wall of the workpiece.

9. The system of claim 1, further comprising a process gas emitted into an interior area defined by an interior wall of the workpiece, the gas being used to assist with ionization during plasma arc deposition coating of the interior wall.

10. The system of claim 1, wherein the workpiece is a metallic automotive vehicle engine block including an internal piston cylinder which is plasma arc deposition coated with a tetrahedrally bonded amorphous carbon thin film by the cathode.

11. The system of claim 1, further comprising:
a plasma arc deposition coating using the cathode having an ion impact energy of at least 10 eV against the workpiece which is metallic; and
a complete coating cycle being no greater than five minutes from when the vacuum is started to when the vacuum ends.

12. A coating system comprising:
an elongated cathode;
at least one magnetic source;
a metallic workpiece including an internal surface defining an internal bore, the internal surface of the workpiece surrounding an outer surface of the cathode;
a vacuum chamber being defined by at least the internal surface of the workpiece and at least one member comprising: (a) a removable end cap or (b) a flexible seal, positioned adjacent at least one open end of the bore; and
the at least one magnetic source being located inside the bore of the workpiece during coating of the internal surface of the workpiece.

13. The system of claim 12, further comprising at least two of the magnetic sources located within the cathode, the magnetic sources being longitudinally arranged relative to each other, and a magnetic force at the outer surface of the cathode being 1-20 milliteslas.

14. The system of claim 13, wherein the at least two magnetic sources are electromagnets which are longitudinally spaced apart from each other, further comprising a programmable controller and an electrical circuit being connected to the electromagnets.

15. The system of claim 12, wherein the at least one magnetic source is located within a hollow center of the cathode, such that the cathode is laterally between the magnetic source and the workpiece.

16. The system of claim 15, further comprising a solid and longitudinally elongated transmission shaft coaxially extending within the cathode, the shaft being attached to the magnetic source, and the shaft and the magnetic source operably moving longitudinal and rotational directions during plasma coating of the internal surface of the workpiece.

17. The system of claim 12, further comprising:
a plasma arc deposition coating using the cathode having an ion impact energy of at least 10 eV against the workpiece; and
a complete coating cycle being no greater than five minutes from when vacuum pressure is started to when the vacuum pressure ends.

18. The system of claim 12, wherein the workpiece is an anode during the coating and a longitudinal length of the cathode is greater than a lateral diameter of the cathode.

19. A coating system comprising:
an elongated cathode including a hollow interior;
multiple magnetic sources located within the hollow interior of the cathode in a longitudinally spaced apart manner, the cathode laterally surrounding the magnetic sources;
a vacuum source connected to a vacuum area surrounding a portion of the cathode; and
the cathode being configured to operably apply a plasma arc deposition coating.

20. The system of claim 19, wherein the magnetic sources are electromagnets which are energizably controlled by a programmable controller.

21. The system of claim 20, further comprising:
an electrical circuit connected to the electromagnets, the controller, the cathode and an anode;
the anode comprising a workpiece including a cylindrical inner surface to be coated; and
the deposition coating having an ion impact energy of 10-250 eV.

22. The system of claim 19, further comprising:
a workpiece including an elongated internal bore within which is inserted the cathode;
at least one member sealing an open end of the bore; and
the vacuum source reducing pressure within the sealed bore to allow the coating to be applied to an internal and metallic workpiece surface defining the bore.

23. A method for coating a workpiece, the method comprising:
(a) inserting a cathode inside an internal bore of the workpiece;
(b) sealing at least one open end of the bore such that the bore acts as part of a vacuum chamber;
(c) generating an arc in a plasma between the cathode and the workpiece, which acts as an anode;
(d) using a magnetic field adjacent the cathode to assist in controlling the arc; and
(e) exposing an exterior of the workpiece to ambient air exterior to the vacuum chamber during the coating.

24. The method of claim 23, further comprising:
reducing pressure within the bore for the coating process; and
moving a magnet, internally located within a hollow center of the cathode, relative to the cathode during the coating process.

25. The method of claim 23, further comprising:
plasma arc deposition coating an internal and metallic workpiece surface surrounding the bore with an ion impact energy of at least 10 eV;
the coating cycle being no greater than five minutes from when vacuum pressure is started to when vacuum pressure ends; and
the internal workpiece surface being coated with a harder material than the remainder of the workpiece adjacent the bore.
